(19) United States
(12) Patent Application Publication
(10) Pub. No.: US 2010/0095609 A1
(43) Pub. Date: Apr. 22, 2010

(54) COMPLEX GENERATOR USING SOLAR AND WIND AND WAVE

(76) Inventor: Yun Se Kim, Busan (KR)

Correspondence Address: GWIPS;Peter T. Kwon, Gwacheon P.O. Box 72, 119 Byeolyang Ro, Gwacheon City, Gyeonggi-Do, 427-600, KR

(21) Appl. No.: 12/449,734

(22) PCT Filed: Feb. 20, 2008
(86) PCT No.: PCT/KR2008/000991

§ 371 Date: Aug. 20, 2009

(30) Foreign Application Priority Data
Feb. 20, 2007 (KR) 10-2007-0017856
Feb. 20, 2008 (KR) 10-2008-0015215

(51) Int. Cl. E04H 12/34; H01L 31/02; F03B 13/20; F03D 9/00

(52) U.S. Cl. 52/173.3; 52/651.01; 290/53; 290/55

(57) ABSTRACT

A combined power generator using solar, wind and wave energies is disclosed. The combined power generator comprises a steel tower structure (2) having a solar energy power generation unit in which a plurality of light collection plates (19) are arranged in multiple rows and columns, a wind energy power generation apparatus which is installed on the top of the steel tower structure (2) and rotates by means of the wind, and a wave energy generation apparatus which is driven by means of the flow of water, wherein the steel tower structure, the wind energy power generation apparatus, and the wave energy generation apparatus are combined.

### TECHNICAL FIELD

The present invention relates to a combined power generator using solar, wind and wave energies, and in particular to a combined power generator using solar, wind and wave energies in which a solar energy generator for generating power using a light collection plate, a wind energy generator for generating power using a pressure generated when wind blows, and a wave energy generator for generating power using waves in sea or river are combined, respectively.

### BACKGROUND ART

An alternative energy has been studied for using energy instead of oil since a natural resource buried under the ground will be surely ended. Many studies disclose various technologies, but their actual applications are not commercial.

It has been recognized that using an unlimited natural energy such as solar, wind and water energies is most ideal, so there are many researches on the same. In one example, there are a solar energy development technology in which the energy from sun light is collected by using a light collection plate for thereby generating power, and a wind energy power development technology in which power is generated by using wings which rotate by means of the force of wing, and a water power technology in which power is generated by using an up and down motion of waves or wave forces in sea or in a river.

Lots of money and area are needed for installing only one facility and system of a solar energy plant. Since a wind energy power facility should be installed separately from a solar energy plant, lots of basic facility area and facility cost are needed for the wind energy power plant. Since there is not disclosed any combined power generation method for using solar, wind and wave energies, a solar energy cannot be generated when it is cloud. In addition, it is impossible to generate powers by using wind energy and wave energy when there are not wind or waves. Since the power facilities installed separately from each other are influenced by means of a weather condition, an inter-operation is needed, but impossible due to the above reasons.

In case that a solar energy plant, a wind energy plant and a wave energy plant are separately installed, there is not disclosed a specific unit for overcoming the above problems occurring in manufacturing electric power by means of an alternative energy. The Korean patent application number 10-2004-0088063 previously invented and filed by the same applicant as the present invention has also a problem for generating power energy when wind force or wave force is weak, and when there is a typhoon.

### DISCLOSURE OF INVENTION

### Technical Problem

Accordingly, it is an object of the present invention to provide a combined power generator using solar, wind and wave energies, which overcomes the problems found in the conventional art.

It is another object of the present invention to provide a combined power generator using solar, wind and wave energies in which a combined power generator using solar, wind and wave energies is installed in a place such as a sea beach, a mountain or a roof of a building. One generator is installed in a corresponding place depending on a solar energy generation, a wind energy generation and a wave energy generation. So, the total cost can be decreased, and a desired motion energy can be obtained when there is a typhoon or a weak wave.

It is further another object of the present invention to provide a combined power generator using solar, wind and wave energies in which a solar cell plates is installed in multiply stacked rows in a power generation structure, so the light collection plate can trace a movement track of the sun for thereby most efficiently collecting solar energies.

### Technical Solution

To achieve the above objects, there is provided a combined power generator using solar, wind and wave energies which comprises a steel tower structure 2 having a solar energy power generation unit in which a plurality of light connection plates 19 are installed in multiple rows and columns, respectively, a wind energy power generation apparatus which is installed at the top of the steel tower structure 2 and rotates by wind, and a wave energy power generation apparatus which is driven by the waves of water.

### ADVANTAGEOUS EFFECTS

In a conventional art, one power plant is separately installed in a place such as a sea beach, a mountain, a river or something for obtaining an alternative energy by using a solar energy, a wind energy and a wave energy, which leads to a lot of cost and installation area. But, in the present invention, there is provided a combined power generation apparatus by using a basic facility needed for each power generation method for thereby saving the total cost. It is possible to strongly rotate a blower by using a twister generating twist wind. The shapes of wings are improved, so an upward wind flow can be used. When there is a typhoon, it is possible to protect a twister and wind force wings. The present invention can be easily installed in a place with less wind and low wind speed. Since a wave energy generation is possible in a sea beach, the use of an alternative natural energy is very efficient.

### BRIEF DESCRIPTION OF THE DRAWINGS

The present invention will become better understood with reference to the accompanying drawings which are given only by way of illustration and thus are not limitative of the present invention, wherein;

FIG. 1 is a view illustrating the construction of a solar energy power generation apparatus of a combined power generator according to the present invention;

FIG. 2 is a view of another example of the present invention;

FIG. 3 is a view illustrating the construction of a wind energy power generator according to the present invention;

FIG. 4 is a view illustrating a wind energy power generator according to another embodiment of the present invention;

FIG. 5 is a view illustrating a wind energy power generator according to further another embodiment of the present invention;

FIG. 6 is a view illustrating the construction of a wave energy power generator according to the present invention while showing the construction that a seesaw motion and a rotation motion are combined, which leads to a power generation;

FIG. 7 is a view illustrating the construction of a wave energy power generator according to another embodiment of the present invention; and

FIG. 8 is a view illustrating a combined power generator according to the present invention.

### BEST MODE FOR CARRYING OUT THE INVENTION

The facilities needed for a basic facility, which is constructed to more efficiently utilize the nature, such as a solar energy facility, a wind energy facility and a wave energy facility are combined, which leads to saving a lot of cost. The light collection plate is installed in South in multiple layers and rows, and the light collection plate can move toward the sun by using a sun tracing sensor in left and right directions, so that it is possible to collect the solar energy in maximum.

In the solar energy power generation facility structure, the side facing coming wind is gradually narrowed and bent, so a twisting wind is generated from an incoming wind. The wind force generated by the wings allows the blower installed in the center to rotate, so the generator is rotated. Rib grooves are formed in each wing with one end of each groove being twisted for enhancing wind efficiency, so it is possible to generate a desired energy by using an upwardly moving airflow.

In addition, an automatic adjusting apparatus such as a speed sensor acting depending on the weak and strong levels of the wind is connected with an auxiliary generator, so it can be selectively driven. With the above construction, a wind force can be decreased when there is a typhoon. So, a safer operation is obtained, and the generated electric power is refined by means of a power adjusting apparatus and is supplied to the battery or the power supply side.

### MODE FOR THE INVENTION

The preferred embodiments of the present invention will be described with reference to the accompanying drawings.

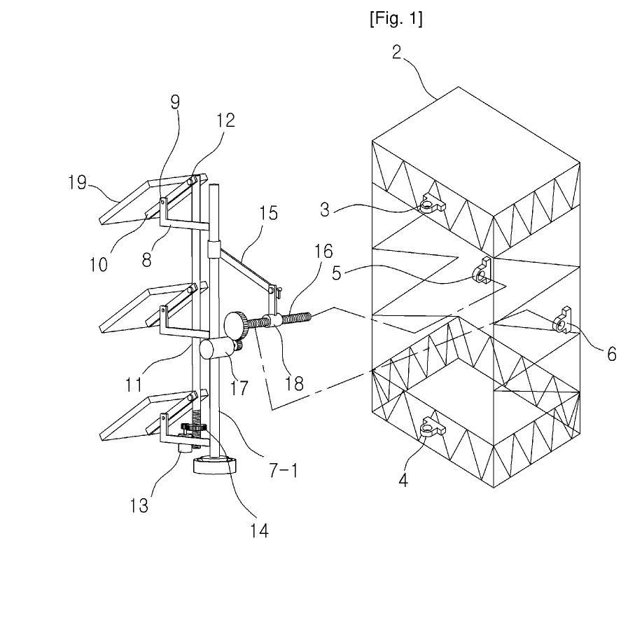

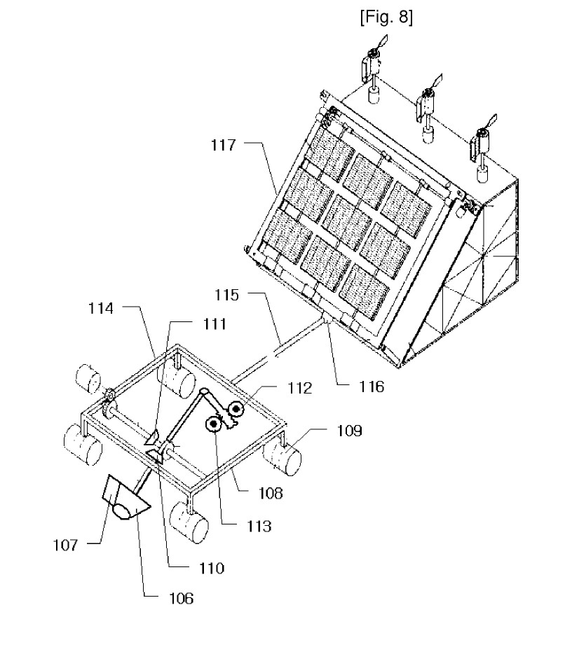

FIG. 1 is a view illustrating the construction of a solar energy power generation apparatus of a combined power generator according to the present invention, and FIG. 8 is a view illustrating a combined power generator according to the present invention.

As shown in FIGS. 1 and 8, the combined power generator according to the present invention comprises a steel tower structure 2 having a solar energy generation unit in which a plurality of light collection plates 19 are arranged in multiple rows and columns, and a wind energy power generation apparatus which is installed on the top of the steel tower structure 2 and rotates by means of wind.

Here, the light collection plate 19 is installed at a slanted angle toward South in which the sun tracks. The light collection plate 19 is movable left and right while tracking the sun with the help of a sun position tracing system depending on the facts that the sun rises East and sunsets in West along its track. In addition, one side of the light collection plate 19 can be tilted up and down depending on the facts that the sun is positioned at a certain slanted angle due to the change of season.

The sun tracing method may be implemented by previously inputting the average position value of the sun in one year and the average position value of the sun in one day or may be automatically implemented by using the sun position tracing system with the help of a photo sensor.

The solar energy power generation apparatus formed of a plurality of light collection plates 19, which are movable left and right, will be described with reference to FIG. 1.

The solar energy power generation apparatus comprises a support unit 8 which is horizontally installed in one side of a vertical rotation tower 7-1, a fixing unit 10 of which its intermediate portion is hinged to the support unit with a frame pin 9, and a light collection plate 19 installed in the fixing unit 10.

The upper and lower adjusting unit includes an upper and lower adjusting tower 11 in which one end of the fixing unit 10 is hinged with a pin 9, and a worm gear 14 is axially installed in its lower side, with the upper and lower adjusting tower 11 being engaged to a bearing box 3, 4 of the steel tower structure 2, and an upper and lower adjusting motor 13 which is tooth-engaged to the worm gear 14.

In the left and right adjusting unit, one end of the left and right adjusting bar 15 having a certain length is fixed on an outer surface of the rotation tower 7-1 at a slanted angle, and the other end of the left and right adjusting bar 15 is hinged to a box gear 18. The box gear 18 is tooth-engaged to a column gear installed in the bearing box 5, 6 of the steel tower structure 2, and the left and right adjusting motor 17 is installed in the end of the column gear 16.

So, the column gear 16 rotates in normal or reverse direction by means of the operation of the left and right adjusting motor 17, and the box gear 18 is movable forward or backward, and the left and right adjusting bar 15 rotates the rotation tower 7-1 in normal or reverse direction, and the support unit 8 and the light collection plate 19 rotate in the horizontal direction.

When the upper and lower adjusting motor 13 rotates, the upper and lower adjusting tower 11 moves up and down along with the rotation of the worm gear 14, and the fixing unit 10 rotates in the vertical direction with respect to the pin 9, and the light collection plate 19 rotates upward and downward.

The left and right adjusting motor 17 and the upper and lower adjusting motor 13 are driven by means of the sun position tracing system. Since it is a conventional art, the detailed descriptions of the same will be omitted.

The light collection plate 19 is movable left and right depending on the position of the sun, so it is possible to collect as much as sun light.

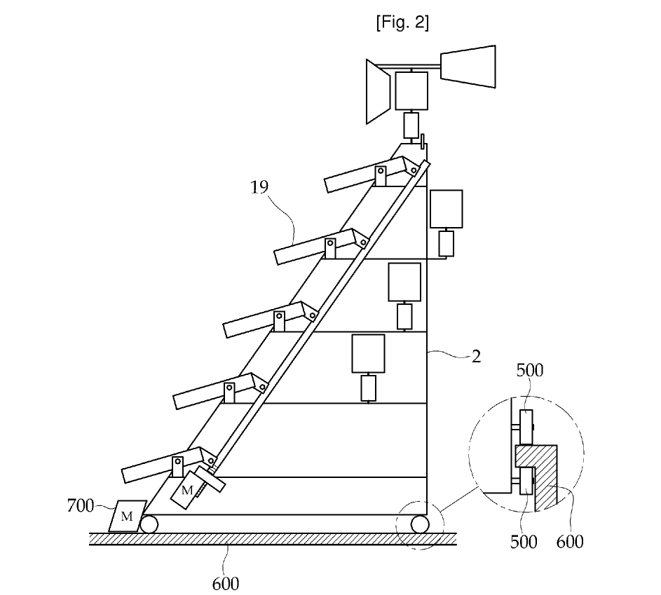

Another embodiment of the present invention will be described with reference to FIG. 2.

As shown in FIG. 2, the solar energy generation unit comprises a support unit 8 which is horizontally installed in a side of the vertical rotation tower 7-1, a fixing unit 10 of which its intermediate portion is hinged to the support unit with a pin 9, and a light collection plate 19 which is installed in the fixing unit 10. The upper and lower adjusting unit comprises an upper and lower adjusting tower 11, in which one end of the fixing unit 10 is hinged to the same with a hinge 9, and a worm gear 14 is axially installed in its lower side, with the upper and lower adjusting tower 11 being fixed to the bearing box 3, 4 of the steel tower structure 2, and an upper and lower adjusting motor 13 which is tooth-engaged to the worm gear 14. In the left and right adjusting unit, one end of the left and right adjusting bar 15 having a certain length is fixed on an outer surface of the rotation tower 7-1 at a slanted angle, and the box gear 18 is hinged to the other end of the left and right adjusting bar 15. The box gear 18 is tooth-engaged to the column gear 16 installed in the bearing box 5, 6 of the steel tower structure 2, and the left and right adjusting motor 17 is installed in the end of the column gear 16.

In case that the size of the solar energy generation unit is large, a certain rotation apparatus is provided in a lower side for preventing the steel tower structure 2 having the light collection plate 19 from falling down and for rotating the same in order to trace the sun.

The rotation apparatus includes a rail wheel 500 in a lower side of the steel tower structure 2, and a ring shaped rail 600 installed on the ground so that the rail wheel 500 is engaged to the same. A motor 700 is installed in a lower side of the steel tower structure 2 for driving the rail wheel 500.

The rail wheel 500 is engaged to the upper and lower sides of the rail 600 and has functions for preventing falling down and for easier operations.

The motor 700 is driven by means of the sun position tracing system, and the steel tower structure 2 having the light collection plate 19 rotates 360° as the rail wheel 500 drives.

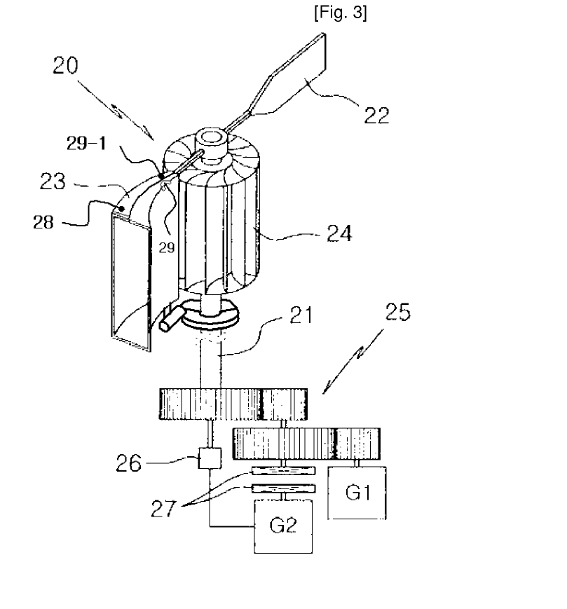

FIG. 3 is a view illustrating the construction of a wind energy power generation apparatus according to the present invention.

As shown in FIG. 3, in the wind energy power generation apparatus 20, a blower 24 is installed at an upper end of a blow shaft 21 for rotating the blower shaft 21. A wind wing 22 is installed at an outer side of the blower 24 and rotates in the direction depending on the direction that wind comes in. A twister 23 is installed in the other side for generating a high pressure and fast wind by making a twisting flow when the air comes in. A speedup gear 25 and generators G1 and G2 are installed at the lower side of the blower shaft 21.

When the wind wing 22 rotates in the direction that wind comes in, the wing flows into the interior of the twister 23 having a wider inlet and a narrow outlet bent in an arc shape, and a high pressure and speed air is sprayed into the blower 24, and the blower 24 having a plurality of rotation wings rotates with respect to the blower shaft 21 by means of the air sprayed from the twister 23. The rotation speed increases by means of the speedup gear 25 for thereby producing a lot of power.

The divided twisters 23 are overlapped and assembled for effectively guiding strong wind when typhoon comes, and the inlet is hinged with a pin 28, rings 29 and 29-1 are formed at the outlet of the twister 23, and the rings 29 and 29-1 are connected with a spring.

When typhoon comes, the strong wind is inputted into the inlet of the twister 23 and is discharged through the outlet. At this time, the rings 29 and 29-1 are widened by means of the force of wind, and the spring is elongated. Part of the wind inputted through the inlet does not flow through the blower 24, so a reliable power generation can be obtained.

In case that the twister 23 is made larger, a motor (not shown) may be further installed at the outlet for controlling the opening and closing operations. The rings 29 and 29-1 are widened by means of the operation of the motor.

A speed sensor 26 is provided in one side of the speedup gear 25 for detecting a rotation speed of the blower 24 or the speedup gear 25. An auxiliary generator G2 is selectively connected with the speedup gear 25 through a clutch 27. The operation of the above construction will be described.

When the wind wing 22 rotates in the direction that wind comes in, the wing flows into the interior of the twister 23 having a wider inlet and a narrow outlet bent in an arc shape, and a high pressure and speed air is sprayed into the blower 24, and the blower 24 having a plurality of rotation wings rotates with respect to the blower shaft 21 by means of the air sprayed from the twister 23. The rotation speed increases by means of the speedup gear 25 for thereby producing a lot of power.

At this time, when high speed wind blows due to typhoon, the rotation speed of the blower 24 is high. So, a product durability may be worsened since the generator may be changed due to over power generation. In this case, the speed sensor 26 detects the rotation speed of the blower 24 or the speedup gear 25. When an abnormal speed occurs, the clutch 27 is attached, and the auxiliary G2 is driven.

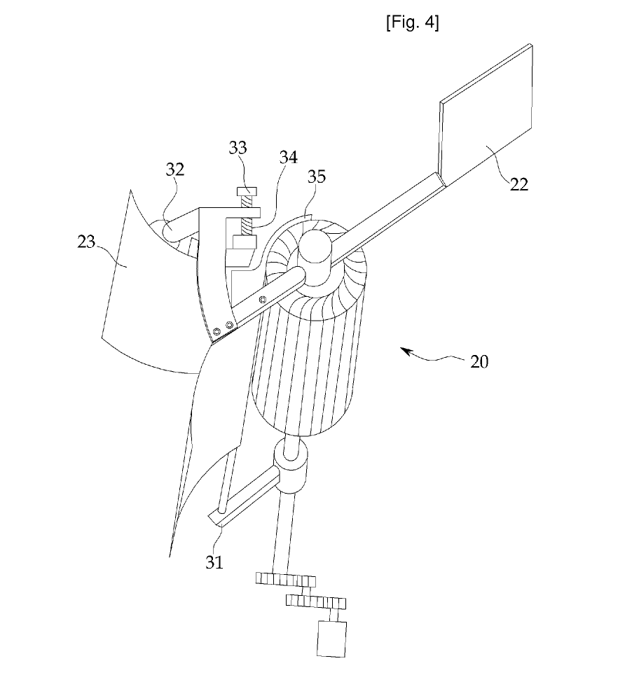

FIG. 4 is a view illustrating a wind energy power generator according to another embodiment of the present invention.

As shown in FIG. 4, support shafts 31 are horizontally installed in the upper and lower sides of the blower shaft. A cover 35 is installed between the support shafts 31 with its rear end covering the blower.

Two twisters 23 are engaged in the support shaft 31 with a support unit pin 32 while being widened from each other. An adjusting bolt 33 having the spring 34 properly pushes the rear end of the twister 23.

The twister 23 is engaged with the helps of the support shaft 31 and the cover 35. Both the twisters 23 are engaged by using another support unit pin 32. The spring 34 is engaged in the shaft of the adjusting bolt 33 and elastically supports the rear side of the twister 23 with a proper force. So, the cover 35 maintains the state of FIG. 4.

The cover 35 covers the blower 20 and prevents the escapes of the wind in usual time.

When the typhoon comes, both the twisters 23 are externally tilted by the force of strong wind, and one twister 23 rotates with respect to the support unit pin 32 and pushes the front side of the cover 35 having a narrowed rear end to the center. The cover 35 covers the blower 20, and a lot of wind flows in other ways, so a reliable power generation can be obtained.

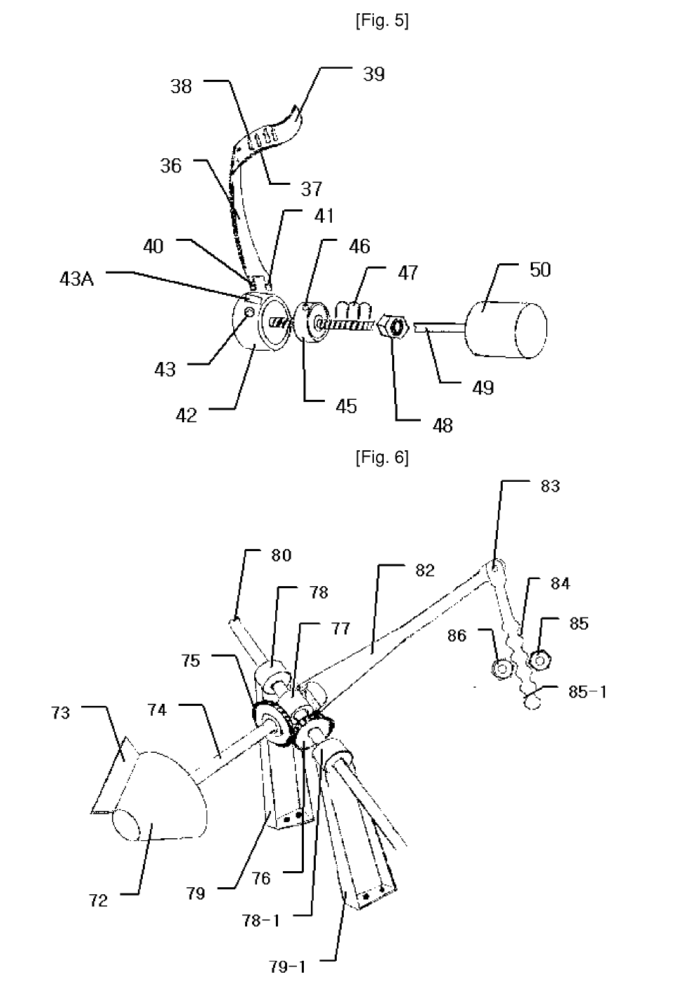

FIG. 5 is a view illustrating a wind energy power generator according to another embodiment of the present invention.

As shown therein, a drum 42 is axially engaged to the column 49 of the generator 50. A wind wing 36 is engaged to an outer surface of the drum 42, and the wind wing 36 rotates by the force of wind, so the generator 50 is driven.

The wind wing 36 is provided with a torsion wing 39 of which its end is upwardly bent at about 45, and a rib wing 38 is formed on an outer surface of the torsion wing 39, and a plurality of shafts 40 and 41 are provided in the other end of the same.

With the above construction, the force can be significantly enhanced by using remote wing, and a propelling force using an up air flow can be obtained by means of the torsion wing 39, so a natural phenomenon can be utilized in maximum.

The shaft 40 is engaged to an insertion member 43 formed on an outer surface of the drum 42, and another shaft 41 is engaged to the adjusting insertion member 43a formed on an outer surface of the drum 42.

The adjusting insertion member 43a is an elongated hole having a certain length.

In case that strong wind such as typhoon blows to the wind wing 36, the wind wing 36 rotates while being slightly twisted with respect to the shaft 40, and the shaft 41 moves backward in the adjusting insertion member 43a, so that the wind wing 36 is twisted for thereby decreasing the resistance of the wind force and preventing the damage.

The shaft 41 inserted through the adjusting insertion member 43a is engaged to the column 49 and is engaged to the adjusting unit 436 of the small drum 45 inserted into the drum 42, and the spring 47 and the nut 48 are engaged to the outer surface of the column 49 for supporting the small drum 45.

When the shaft 41 moves backward in the adjusting insertion member 43a, the small drum 45 moves backward along the column 49. At this time, the spring 47 keeps being compressed.

When the wind force decreases and is smaller than the flexing force of the spring 47, the shaft 41 moves forward in the adjusting insertion member 43a by the elastic force generated as the spring 47 is recovered, and the wind wing 36 returns its initial state with the help of the above operation.

When there is a constant wind speed, the position of the wind wing 36 is normal, and when a wind speed is high, the wind wing 36 is distorted, and the contact area with the wind decreased for thereby preventing damages.

FIG. 6 is a view illustrating the construction of a wave energy power generation apparatus according to the present invention. The above apparatus uses waves in sea or river for generating with the helps of seesaw motion and rotation motion.

As shown in FIG. 6, the above apparatus comprises a plurality of support units 79 and 79-1 vertically installed, a trust (frame) installed in the support units 79 and 79-1 and having a box bearing 78, 78-1, and a column 74 and the trust lever 82 installed in the trust. A buoyancy tank 72 having a webfoot 73 is installed at the end of the column 74, and a spur gear 84 is hinged to an end of the trust lever 82. The spur gear 84 is tooth-engaged with the latch gear 85, 86 connected with the column of the first generator (not shown).

So, the column 74 and the trust lever 82 perform a seesaw motion by means of the wave motion with respect to the support unit 79, 79-1. Preferably, the column 73 is shorter, and the trust lever 82 is longer. With the above construction, the seesaw motion can be more effectively performed by the wave motion of the buoyancy tank 72 floating on the water with respect to even smaller wave, and the trust lever 82 and the spur gear 84 move up and down.

The latch gear 85, 85 is rotated by means of the up and down motions of the spur gear 84, and the rotational force of the latch gear 85, 86 is transferred to the first generator (not shown) through the column (not shown) for thereby generating power.

Since the latch gear 85, 86 repeatedly performs normal and reverse rotations. In a preferred embodiment, the column 74 can be rotated only when it rotates in the normal direction by adapting one way clutch bearing or can have an idle rotation when it rotates in reverse direction.

As shown in FIG. 6, the buoyancy tank 72 is formed in a conical shape, and a webfoot 73 is formed in its outer surface, so that the rotation can be performed along the direction of wave flow.

The column 74 and the second generator column 80 are tooth-engaged with a helical gear 75, 76, and the rotational forces of the buoyancy tank 72 and the column 74 are transferred to the second generator column 80 through the helical gear 75, 76, so that the second generator (not shown) generates power.

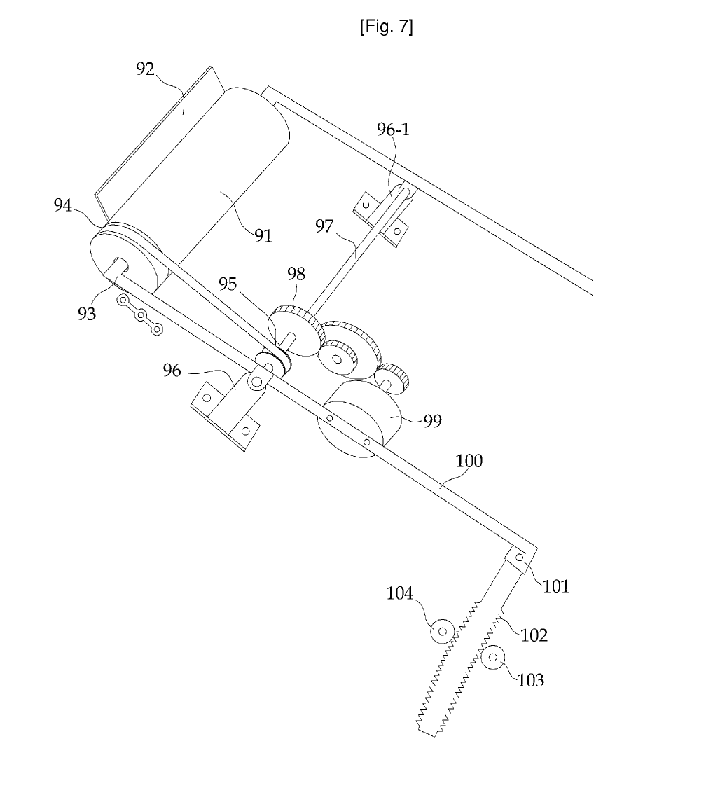

FIG. 7 is a view illustrating the construction of another wave energy power generation apparatus according to the present invention.

As shown in FIG. 7, the above apparatus comprises a plurality of trust levers 100 which are hinged to the fixing unit 96, 96-1 spaced-apart from each other and are constructed to perform a seesaw motion with one side of each lever being shorter, and with the other side of the same being longer, a buoyancy drum 91 which is rotatably installed in the column 93 connecting the shorter portion of the trust lever 100 and has a webfoot 92 on its outer surface, a plurality of gears 98 which are connected with the rotary shaft 94 of the buoyancy drum 91 through a connection member and which are tooth-engaged with the sprockets of the shaft rod installed between the fixing units 96 and 96-1, a third power generator which is tooth-engaged with the gear 98, a spur gear 102 which is hinge to a longer end of the trust lever 100, a plurality of latch gears 103 and 104 which are tooth-engaged to the spur gear 102, and a fourth generator which is connected with the latch gears 103 and 104 for thereby generating power.

The connection unit is made of a belt, a chain or a crankshaft.

As the buoyancy 91 floating on the water depending on the flow of water rotates, the third generator generates power with the help of the rotations of the rotary shaft 94 and the connection unit.

The trust lever 100 performs a seesaw motion by means of the up and down motions of the buoyancy drum 91 with the helps of the up and down motions of water, and the spur gear 102 moves up and down, and the latch gear 103, 104 rotates, so that the fourth generator generates power.

FIG. 8 is a view illustrating the combined power generator according to the present invention.

As shown in FIG. 8, a float 109 is installed at a lower side of the trust 108 for allowing the wave energy power generation apparatus 114 to float on the sea, and the wave energy power generation apparatus is installed in the trust 108 with reference to FIG. 5.

When it rotates with the help of the webfoot 107 attached to the buoyancy tank 106, the rotational force is transferred to the second generator through the helical gear 110, 111 for thereby generating power.

The spur gear 102 moves up and down by means of the seesaw motion of the trust lever connected to the buoyancy tank 106, so the latch gears 112 and 113 rotate, and the first generator generates power with the help of the operations of the latch gears 112 and 113.

Since the construction of the wave energy power generation apparatus is well disclosed in the Korean patent application (application number 2004-0088063 filed with the KIPO on Oct. 29, 2004) by the same applicant as the present invention, the descriptions of the same will be omitted.

As shown in FIGS. 1 through 8, the heat energy collected from the light collection plate 19 is processed through an electricity refining apparatus (not shown) with the helps of the known solar energy generation apparatuses, and the rotational force of the blower 20 rotating by means of wind allows the generator G1 to drive, and the power so produced is processed through the electricity refining apparatus. In the present invention, the over load due to the increase of the rotation speed is prevented, and the auxiliary generator G2 can be automatically driven for thereby generating a lot of power at the same time.

As the spur gear and the latch gears rotate in cooperation with the seesaw motion of the trust lever of the wave energy power generation apparatus, the first and fourth generators are driven, and the power so produced is processed through the electricity refining apparatus, so that a combined power generation is obtained through the batteries (not shown).

The rotational force generated with the help of the rotation of the buoyancy tank is transferred to the column, and the second and third generators are driven for thereby producing power.

The combined power generator according to the present invention is not limited to the examples disclosed above. The combined power generators can be installed in multiple layer structures depending on the area in which the combined power generator is to be installed, and can be installed in a lateral direction.

### INDUSTRIAL APPLICABILITY

As described above, a basic facility necessarily needed for a power generation is combined for thereby manufacturing a combined power generator, which leads to saving the cost and to maximizing the energy production efficiency with the help of the improved structure as compared to the conventional art in which each facility is separately installed in a place such as a sea beach, a mountain and a river for producing an alternative energy by using a sun light, a wind energy and a wave energy.

As the present invention may be embodied in several forms without departing from the spirit or essential characteristics thereof, it should also be understood that the above-described examples are not limited by any of the details of the foregoing description, unless otherwise specified, but rather should be construed broadly within its spirit and scope as defined in the appended claims, and therefore all changes and modifications that fall within the meets and bounds of the claims, or equivalences of such meets and bounds are therefore intended to be embraced by the appended claims.

### Sequence Listing

power generator, wind energy, wave energy, drum, pin

What is claimed is:

1-10. (canceled)

11. A combined power generator, comprising:
a steel tower structure (2) having a solar energy power generation unit in which a plurality of light collection plates (19) is arranged in multiple rows and columns;
a wind energy power generation apparatus which is installed on the top of the steel tower structure (2) and rotates by means of wind in a combined structure with the steel tower structure, said solar energy power generation being provided with a support unit horizontally installed in a side surface of a vertical rotation tower (7-1), a fixing unit (10) of which its intermediate portion is hinged to the support unit with a pin (9), and a light collection plate (19) which is installed in the fixing unit (10);
an upper and lower adjusting means which is provided with an upper and lower adjusting tower (11) which is hinged with one end of the fixing unit (10) with a pin (9) and is engaged with a bearing box (3, 4) of the steel tower structure (2) with a worm gear (14) being axially engaged in its lower side, and an upper and lower adjusting motor (13) which is tooth-engaged with the worm gear (14); and
a left and right adjusting means in which one end of the left and right adjusting bar (15) having a certain length is fixed on an outer surface of the rotation tower (7-1) at a slanted angle, and a gear box (18) is hinged at the other end of the left and right adjusting bar (15), and the box gear (18) is tooth-engaged with a column gear (16) installed in the bearing box (5, 6) of the steel tower structure (2), and a left and right adjusting motor (17) is installed at an end of the column gear (16).

12. The combined power generator of claim 11, wherein said wind energy power generation apparatus is constructed as a blower (24) is installed in an upper side of the blower shaft (21), and a wind wing (22) rotating in the direction that wind comes is installed in an outer side of the blower (24), and a twister (23) is installed in the other outer side of the same for generating twisting wind, and a speedup gear (25) and generators (G1, G2) are installed in the lower side of the blower shaft (21), and the half-divided twisters (23) are overlapped and assembled, and its inlet portion is hinged with a pin (28), and a ring (29) and a ring (29-1) are formed at the outlet of the twister (23), and the rings (29, 29-1) are connected with a spring.

13. The combined power generator of claim 12, wherein a speed sensor (26) is installed in one side of the speedup gear (25) for detecting the rotation speed of the blower (24) or the speedup gear (25), and an auxiliary generator (G2) selectively connected with the gear of the speedup gear (25) through the clutch (27) is installed in one side of the same.

14. The combined power generator of claim 11, wherein in said wind energy power generation apparatus, a support shaft (31) is horizontally formed in the upper and lower sides of the blower shaft, and a cover (35) is installed between the support shafts (31) for covering the blower with its rear end, and two widened twisters (23) are hinged to the support shaft (31) with a support unit pin (32), and the adjusting bolt (33) having a spring (34) properly pushes the rear end of the twister (23).

15. The combined power generator of claim 11, wherein in said wind energy power generation apparatus, a drum (42) is axially installed in the column of the generator (50), and a wind wing (36) is engaged in an outer surface of the drum (42), and a torsion wing (39) is upwardly formed at an end of the wind wing (36), and a rib wing (38) is formed on an outer surface of the torsion wing (39), and a plurality of shafts (40, 41) are formed on the other end of the same, and the shaft (40) is engaged to the insertion member (43) formed on an outer surface of the drum (42), and another shaft (41) is engaged to the elongated hole-shaped adjusting insertion member (43a) formed on an outer surface of the drum (42), and the shaft (41) inserted through the adjusting insertion member (43a) is engaged to the column (49) and is engaged to the adjusting unit (46) of the small drum (45) inserted into the drum (42), and the spring (47) and the nut (48) are engaged to the outer surface of the column (49) for supporting the small drum (45), and as the shaft (41) moves backward in the adjusting insertion unit (43a) by means of strong wind with respect to the shaft (40), the wind wing (36) is twisted for thereby decreasing the resistance of the wind force.

16. A combined power generator, comprising:
a steel tower structure (2) having a solar energy power generation unit in which a plurality of light collection plates (19) is arranged in multiple rows and columns;
a wind energy power generation apparatus which is installed on the top of the steel tower structure (2) and rotates by means of wind in a combined structure with the steel tower structure, said solar energy power generation being provided with a support unit horizontally installed in a side surface of a vertical rotation tower (7-1), a fixing unit (10) of which its intermediate portion is hinged to the support unit with a pin (9), and a light collection plate (19) which is installed in the fixing unit (10);
an upper and lower adjusting means which is provided with an upper and lower adjusting tower (11) which is hinged with one end of the fixing unit (10) with a pin (9) and is engaged with a bearing box (3, 4) of the steel tower structure (2) with a worm gear (14) being axially engaged in its lower side, and an upper and lower adjusting motor (13) which is tooth-engaged with the worm gear (14);
a left and right adjusting means in which one end of the left and right adjusting bar (15) having a certain length is fixed on an outer surface of the rotation tower (7-1) at a slanted angle, and a gear box (18) is hinged at the other end of the left and right adjusting bar (15), and the box gear (18) is tooth-engaged with a column gear (16) installed in the bearing box (5, 6) of the steel tower structure (2), and a left and right adjusting motor (17) is installed at an end of the column gear (16); and
a rotation apparatus which is provided in a lower side of the steel tower structure (2) for tracing the position of the sun and includes a rail wheel (500) engaged at a lower side of the steel tower structure (2), a motor (700) connected with the sun position tracing system for driving the rail wheel (500), and a ring shaped rail (600) which is installed on the ground with the rail wheel (500) being engaged thereto.

17. A combined power generator, comprising:
a steel tower structure (2) having a solar energy power generation unit in which a plurality of light collection plates (19) is arranged in multiple rows and columns;
a wind energy power generation apparatus which is installed on the top of the steel tower structure (2) and rotates by means of the wind; and
a wave energy generation apparatus which is driven by means of the flow of water, wherein said steel tower structure, said wind energy power generation apparatus, and said wave energy generation apparatus are combined;
wherein said wave energy generation apparatus comprises a plurality of support units (79, 79-1), which are vertically installed, a trust which is installed in the support units (79, 79-1) and has a box bearing (78, 78-1), and a column (74) and a trust lever (82) which are installed in the trust, and a buoyancy tank (72) having a webfoot (73) is installed at the end of the column (74), and a spur gear (84) is hinged to an end of the trust lever (82), and the spur gear (84) is tooth-engaged with the latch gear (85, 86) connected with the column of the first generator, and the column (74) is tooth-engaged with the second generator column (80) of the second generator and the helical gear (75, 76).

18. The combined power generator of claim 17, wherein said trust has buoyancy at its lower side and floats on the water.

19. The combined power generator of claim 17, wherein said wave energy power generation apparatus includes a plurality of trust levers (100) which are hinged to space-apart fixing units (96, 96-1) and perform seesaw motions with one side of each of the same being shorter, and the other side of the same being longer, a buoyancy drum (91) which is rotatably engaged to the column (93) for connecting a shorter portion of the trust lever (100) and has a webfoot (92) on its outer side, a sprocket of a shaft rod which is connected to the rotary shaft (94) of the buoyancy drum (91) with a connection means and is installed between the fixing units (96, 96-1), a plurality of gears (98) which are tooth-engaged with the sprocket, a third power generator which is tooth-engaged with the gear (98) and generates power, a spur gear (102) which is hinged to a longer end of the trust lever (100), a plurality of latch gears (103, 104) which are tooth-engaged with the spur gear (102), and a fourth power generator which is connected with the latch gears (103, 104) and generates power.

20. The combined power generator of claim 17, further comprising a solar energy power generation provided with a support unit (8) horizontally installed in a side surface of a vertical rotation tower (7-1), a fixing unit (10) of which its intermediate portion is hinged to the support unit with a pin (9), and a light collection plate (19) which is installed in the fixing unit (10), an upper and lower adjusting means, which is provided with an upper and lower adjusting tower (11) which is hinged with one end of the fixing unit (10) with a pin and has a worm gear at its lower side, and an upper and lower adjusting motor (13) which is tooth-engaged with the worm gear (14); and a left and right adjusting means in which one end of the left and right adjusting bar (15) having a certain length is fixed on an outer surface of the rotation tower (7-1) at a slanted angle, and a gear box (18) is hinged at the other end of the left and right adjusting bar (15), and the box gear (18) is tooth-engaged with a column gear (16) installed in the bearing box (5, 6) of the steel tower structure (2), and a left and right adjusting motor (17) is installed at an end of the column gear (16), wherein in said wind energy power generation apparatus, a blower (24) is installed on the top of the blower shaft (21), and a wind wing (22) rotating depending on the direction that wind comes in is provided at an outer side of the blower (24), and the inlet is hinged with a pin as the half-divided parts are overlapped and assembled on the other outer side, and a ring (29) and a ring (29-1) are formed at the outlet of the twister (23), and the twister (23) formed by connecting the rings (29, 29-1) is installed, and the speedup gear (25) and the generators (G1, G2) are installed at the lower side of the blower shaft (21).
